(19) United States
(12) Patent Application Publication
(10) Pub. No.: US 2025/0266408 A1
(43) Pub. Date: Aug. 21, 2025

(54) PASSIVE COMPONENT EMBEDDED SUBSTRATE AND SEMICONDUCTOR PACKAGE INCLUDING THE SAME

(71) Applicant: SAMSUNG ELECTRONICS CO., LTD., Suwon-si (KR)

(72) Inventors: Sunjun KIM, Suwon-si (KR); Hyon-Chol KIM, Suwon-si (KR)

(73) Assignee: SAMSUNG ELECTRONICS CO., LTD., Suwon-si (KR)

(21) Appl. No.: 18/811,512

(22) Filed: Aug. 21, 2024

(30) Foreign Application Priority Data
Feb. 19, 2024 (KR) 10-2024-0023376

(51) Int. Cl. H01L 25/16; H01L 23/00; H01L 23/31; H01L 23/538; H01L 29/92

(52) U.S. Cl. CPC H01L 25/16; H01L 23/3135; H01L 23/5385; H01L 24/24; H01L 24/25; H01L 2224/24146; H01L 2224/2518; H10D 1/62

(57) ABSTRACT

A passive component embedded substrate is provided and includes a core substrate including a core insulating layer that includes a cavity, a passive component, a thickness supplementary layer attached to a first surface of the passive component, and an encapsulant that fills the cavity and is on the passive component, wherein the thickness supplementary layer and at least a portion of the passive component is within the cavity.

### CROSS-REFERENCE TO RELATED APPLICATION

This application claims priority to and the benefit of Korean Patent Application No. 10-2024-0023376, filed in the Korean Intellectual Property Office on Feb. 19, 2024, the entire contents of which are incorporated herein by reference.

### BACKGROUND

### 1. Field

Embodiments of the present disclosure relate to a passive component embedded substrate and a semiconductor package including the same.

### 2. Description of the Related Art

As various efforts are focused on improving characteristics of semiconductor packages, methods have been proposed to embed passive components, such as multi-layer ceramic capacitors (MLCC) and silicon capacitors, on a substrate on which a semiconductor package is mounted, and to electrically connect the embedded passive components to a semiconductor chip. Meanwhile, among various passive components, the silicon capacitors have an advantage of providing high reliability, high performance, and excellent electrical characteristics.

### SUMMARY

Embodiments of the present disclosure provide a passive component embedded substrate and a semiconductor package including the same that prevent problems that may occur due to a differences in thickness between a core substrate and a passive component.

According to embodiments of the present disclosure, a passive component embedded substrate is provided and includes: a core substrate including a core insulating layer that includes a cavity; a passive component; a thickness supplementary layer attached to a first surface of the passive component; and an encapsulant that fills the cavity and is on the passive component, wherein the thickness supplementary layer and at least a portion of the passive component is within the cavity.

According to embodiments of the present disclosure, a passive component embedded substrate is provided and includes a core substrate including: a core insulating layer that includes a cavity; a first core wiring layer and a second core wiring layer respectively on two surfaces of the core insulating layer that face away from each other; and a through via that penetrates the core insulating layer such as to electrically connect the first core wiring layer and the second core wiring layer. The passive component embedded substrate further includes: a passive component including an electrode on a first surface of the passive component; a thickness supplementary layer attached to a second surface of the passive component, that is opposite to the first surface; an encapsulant on the passive component; a first wiring structure on the first surface of the passive component and electrically connected to each of the core substrate and the passive component; and a second wiring structure on the second surface of the passive component and electrically connected to the core substrate, wherein the thickness supplementary layer and at least a portion of the passive component is within the cavity.

According to embodiments of the present disclosure, a semiconductor package is provided and includes a passive component embedded substrate, and a semiconductor chip on the passive component embedded substrate and electrically connected to the passive component embedded substrate. The passive component embedded substrate includes: a core substrate including a core insulating layer including a cavity; a passive component including an electrode on a first surface of the passive component; a thickness supplementary layer attached to a second surface of the passive component, that is opposite to the first surface; an encapsulant on the passive component; a first wiring structure on the first surface of the passive component and electrically connected to each of the core substrate and the passive component; and a second wiring structure on the second surface of the passive component and electrically connected to the core substrate, wherein a thickness of the passive component is 600 μm to 780 μm, wherein a thickness of the core insulating layer is thicker than the thickness of the passive component, and wherein the semiconductor chip is electrically connected to the passive component by the first wiring structure.

### BRIEF DESCRIPTION OF DRAWINGS

FIG. 1 illustrates a cross-sectional view of a passive component embedded substrate according to an embodiment of the present disclosure.

FIG. 2 to FIG. 15 illustrate manufacturing process diagrams of a passive component embedded substrate according to an embodiment of the present disclosure.

FIG. 16 illustrates a cross-sectional view of a passive component embedded other substrate according to an embodiment of the present disclosure.

FIG. 17 illustrates a cross-sectional view of a semiconductor package including a passive component embedded substrate according to an embodiment of the present disclosure.

### DETAILED DESCRIPTION

Hereinafter, non-limiting example embodiments of the present disclosure will be described more fully with reference to the accompanying drawings, in which various example embodiments of the present disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element may be arbitrarily illustrated for ease of description, and embodiments of the present disclosure are not limited to the example embodiments illustrated in the drawings. In the drawings, the thicknesses of layers, films, panels, regions, areas, etc., may be exaggerated for clarity. In the drawings, for ease of description, the thicknesses of some layers and areas may be exaggerated.

Throughout this specification and the claims that follow, when it is described that an element is “coupled or connected” to another element, the element may be “directly coupled or connected” to the other element or “indirectly coupled or connected” to the other element through a third element. In a similar point of view, this includes not only “physically connected” but also “electrically connected.”

In addition, unless explicitly described to the contrary, the word “comprise” (or include”) and variations such as “comprises” (or “includes”) or “comprising” (or “including”) will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In addition, throughout the specification, sequential numbers such as “first,” “second,” and the like are used to distinguish a constituent element from other constituent elements that are the same as or similar to it, and are not necessarily used to refer to a specific component. Accordingly, a configuration referred to as a “first” constituent element in a specific portion of the present specification may be referred to as a “second” constituent element in other portions of the present specification.

In addition, throughout the specification, singular references to certain constituent elements include references to a plurality of these constituent elements, unless specifically stated to the contrary. For example, “insulating layer” may be used to mean not only one insulating layer, but also a plurality of insulating layers, such as two, three, or more.

In addition, throughout the specification, references to one side and the other side are intended to distinguish different sides from each other, and are not necessarily intended to limit it to a specific side. Accordingly, a side referred to as “one” side in a specific portion of the present specification may be referred to as the “other” side in other portions of the present specification.

Hereinafter, a passive component embedded substrate according to embodiments of the present disclosure will be described with reference to the accompanying drawings.

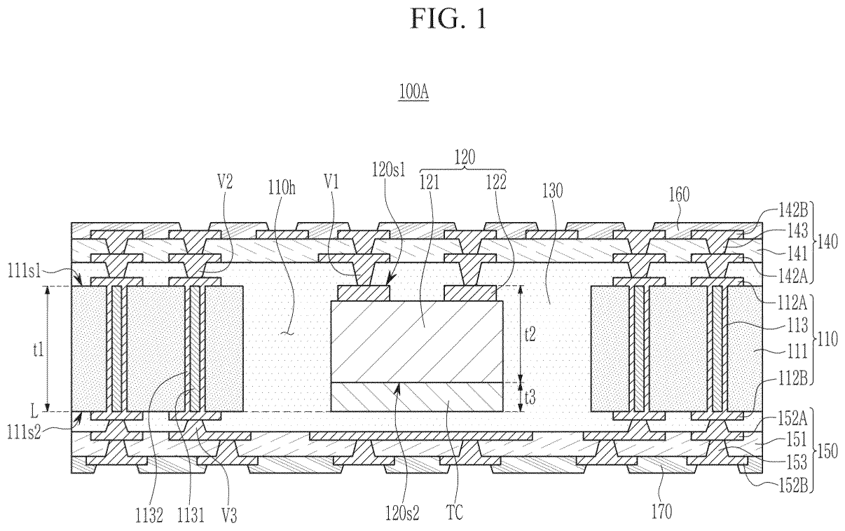

Referring to FIG. 1, a passive component embedded substrate 100A may include a core substrate 110 having a cavity 110h, a passive component 120 in which a thickness supplementary layer TC is attached to one surface 120s2 of the passive component 120 and that is disposed within the cavity 110h, an encapsulant 130 that fills the cavity 110h and covers at least a portion of the passive component 120, a first wiring structure 140 and a second wiring structure 150 respectively disposed on two surfaces of the core substrate 110 facing away from each other, and a first protective layer 160 and a second protective layer 170 respectively disposed on the first wiring structure 140 and the second wiring structure 150.

The cavity 110h may extend from one surface of the core substrate 110 toward the other surface of the core substrate 110 to penetrate the core substrate 110 in a thickness direction of the core substrate 110, and may surround the passive component 120 disposed in the cavity 110h.

The core substrate 110 may include a core insulating layer 111 and one or more core wiring layers (e.g., a first core wiring layer 112A and a second core wiring layer 112B). For example, the core substrate 110 may include the core insulating layer 111, the first core wiring layer 112A and the second core wiring layer 112B respectively disposed on two surfaces of the core insulating layer 111 facing away from each other, and a through via 113 that penetrates the core insulating layer 111 to electrically connect the first core wiring layer 112A and the second core wiring layer 112B. However, the number of the core insulating layers and/or the core wiring layers included in the core substrate 110 is not limited to the number shown in the drawings. For example, the core substrate 110 may further include an additional core insulating layer and/or a core wiring layer disposed on at least one from among the one surface 111s1 and the other surface 111s2 of the core insulating layer 111. Alternatively, the core substrate 110 may include only the core insulating layer 111 and may not include the core wiring layers (e.g., the first core wiring layer 112A and the second core wiring layer 112B), and in this case, the first wiring structure 140 and the second wiring structure 150 may be electrically connected to each other through a conductive post (e.g., a pillar) penetrating the core substrate 110 and the encapsulant 130.

The core insulating layer 111 may improve rigidity of the substrate to suppress warpage.

The core insulating layer 111 may have a great thickness to control the warpage of the substrate. For example, the core insulating layer 111 may have a thickness greater than a thickness of each of a first insulating layer 141 of the first wiring structure 140 and a second insulating layer 151 of the second wiring structure 150. A thickness t1 of the core insulating layer 111 may be 800 μm or more, 900 μm or more, 1000 μm or more, 1100 μm or more, or 1200 μm or more.

As a material of the core insulating layer 111, an insulating material may be used, for example, at least one from among a thermosetting resin such as an epoxy resin, a thermoplastic resin such as polyimide, a prepreg (PPG), an Ajinomoto build-up film (ABF), and FR-4 may be used.

The first core wiring layer 112A may be disposed on one surface 111s1 of the core insulating layer 111, and the second core wiring layer 112B may be disposed on the other surface 111s2 of the core insulating layer 111. Alternatively, the first core wiring layer 112A and the second core wiring layer 112B may be at least partially embedded in one surface 111s1 and the other surface 111s2 of the core insulating layer 111, respectively, and this embodiment is also included in the present disclosure.

As a material of each of the first core wiring layer 112A and the second core wiring layer 112B, a conductive material may be used. For example, each of the first core wiring layer 112A and the second core wiring layer 112B may include copper (Cu), aluminum (Al), nickel (Ni), gold (Au), platinum (Pt), silver (Ag), or an alloy thereof.

The through via 113 may include an insulating material 1131 filled therein and a conductive material 1132 surrounding the insulating material 1131. The through via 113 may be formed by, for example, forming a plating layer on the wall of a via hole penetrating the core insulating layer 111 and filling the inside thereof with an insulating material. The through via 113 may have a cylindrical shape, but is not limited thereto, and may have other shapes such as an hourglass shape.

An electrode 122 may be disposed on one surface 120s1 of the passive component 120, and the thickness supplementary layer TC may be attached to the other surface 120s2 of the passive component 120. The electrode 122 may, for example, have a shape protruding from one surface 120s1 of the passive component 120, but is not limited thereto.

At least a portion of the passive component 120 may be disposed within the cavity 110h together with the thickness supplementary layer TC. For example, the passive component 120 may be entirely disposed within the cavity 110h. Alternatively, a portion of the passive component 120 such as, for example, one surface 120s1 on which the electrode 122 is disposed and an area of a side surface adjacent thereto, may protrude above the cavity 110h depending on a thickness t2 thereof.

The passive component 120 may be disposed within the cavity 110h of the core substrate 110 to be spaced apart from a wall surface of the cavity 110h by a predetermined distance. A space between the wall surface of the cavity 110h and the passive component 120 may be filled with the encapsulant 130.

The passive component 120 may be a thin silicon capacitor, and may include a semiconductor substrate 121, such as a silicon substrate, and an electrode 122. In this case, the thickness supplementary layer TC may be attached to the semiconductor substrate 121. The silicon capacitor may provide high reliability, high performance, and excellent electrical characteristics. However, the passive component 120 of embodiments of the present disclosure are not limited to the silicon capacitor, and the passive component 120 may be variously changed according to embodiments.

The passive component 120 may have a thin thickness, and the thickness t2 of the passive component 120 may be thinner than a thickness of the core insulating layer 111. The thickness t2 of the passive component 120 may be equal to or greater than the sum of a thickness of the semiconductor substrate 121 and a thickness of the electrode 122. For example, the thickness t2 of the passive component 120 may be 600 μm to 780 μm. The passive component 120 may be manufactured based on a wafer and thus have a thin thickness within the range described above. In addition, the thickness t2 of the passive component 120 may be 50 to 75% of the thickness t1 of the core insulating layer 111.

Meanwhile, as a method of embedding passive components in a substrate, a method of forming a cavity in a core substrate, disposing the passive component in the cavity, and then filling the remaining space of the cavity with an encapsulant may be considered. In this case, with respect to a comparative embodiment, when the difference in thickness between the core substrate and the passive component is large, voids may occur when filling the encapsulant. In addition, with respect to the comparative embodiment, problems such as limited access to equipment for disposing passive components in the cavity and increased difficulty in aligning may also occur.

According to embodiments of the present disclosure, by attaching the thickness supplementary layer TC to the passive component 120, a thickness difference between the core insulating layer 111 and the passive component 120 may be supplemented. Therefore, it is possible to prevent problems that may occur due to the difference in thickness between them, such as the occurrence of voids when filling the encapsulant 130, limited access to equipment, and increased difficulty in aligning.

Therefore, it may be desirable that a sum of the thickness t2 of the passive component 120 and the thickness t3 of the thickness supplementary layer TC is equal to or thicker than the thickness t1 of the core insulating layer 111. However, according to embodiments, the sum of the thickness t2 of the passive component 120 and the thickness t3 of the thickness supplementary layer TC may be slightly thinner than the thickness t1 of the core insulating layer 111.

A surface opposite to a surface attached to the passive component 120 of the thickness supplementary layer TC (e.g., a surface facing the second wiring structure 150) may be coplanar with one surface 111s2 of the core insulating layer 111. Therefore, the opposite surface of the surface attached to the passive component 120 of the thickness supplementary layer TC and one surface 111s2 of the core insulating layer 111 may be disposed at the same level L. As described later with respect to the manufacturing process of the passive component embedded substrate 100A according to the embodiment, the thickness supplementary layer TC is disposed in the cavity 110h while being attached to the passive component 120, so that one surface of the thickness supplementary layer TC may have a coplanar structure with one surface 111s2 of the core insulating layer 111. However, depending on the manufacturing process, the surface of the thickness supplementary layer TC that is opposite to the surface of the thickness supplementary layer TC that is attached to the passive component 120 may be coplanar with the surface of the second core wiring layer 112B protruding from the core insulating layer 111 (e.g., the surface facing the second wiring structure 150). In the present disclosure, “coplanar” means being disposed at substantially the same level, and is a concept that includes not only cases of being exactly the same but also subtle level differences that may occur due to errors in the process.

In addition, a side surface of the thickness supplementary layer TC may be coplanar with a side surface of the passive component 120 in a plan view. The thickness supplementary layer TC may be attached to the passive component 120 in a wafer state before the passive component 120 is separated into an individual component, and may be diced together with the passive component 120 to have a structure in which the side surface thereof are coplanar with the side surface of the passive component 120 in a plan view.

A thickness t3 of the thickness supplementary layer TC is not particularly limited and may be appropriately adjusted depending on the thickness t1 of the core insulating layer 111 and the thickness t2 of the passive component 120.

The material of the thickness supplementary layer TC is also not particularly limited, and for example, an adhesive film made of an organic material, a conductive tape made of an inorganic material, or a conductive foil may be used.

The encapsulant 130 may cover at least a portion of the passive component 120, thereby protecting it.

In the embodiment, the encapsulant 130 may fill the cavity 110h and cover each of the passive component 120 and the thickness supplementary layer TC. For example, the encapsulant 130 may cover the side surface of each of the passive component 120 and the thickness supplement layer TC, one surface 120s1 of the passive component 120, and the surface of the thickness supplementary layer TC that is opposite of the surface of the thickness supplementary layer TC attached to the passive component 120. In this case, the encapsulant 130 may extend onto at least one from among two surfaces of the core substrate 110 facing away from each other and further cover it.

The first wiring structure 140 may be disposed on one surface of the core substrate 110 to be electrically connected to each of the core substrate 110 and the passive component 120. The encapsulant 130 may be present between the first wiring structure 140 and one surface of the core substrate 110. For electrical connection between the first wiring structure 140 and the core substrate 110, the passive component embedded substrate 100A may further include a first via V1 penetrating the encapsulant 130 and electrically connecting the first wiring structure 140 to the electrode 122 of the passive component 120, and a second via V2 penetrating the encapsulant 130 and electrically connecting the first wiring structure 140 to the first core wiring layer 112A of the core substrate 110.

A conductive material may be used as the material of each of the first via V1 and the second via V2, and each of them may include, for example, copper (Cu), aluminum (Al), nickel (Ni), gold (Au), platinum (Pt), silver (Ag), or an alloy thereof. Each of the first via V1 and the second via V2 may have a tapered shape whose width is narrowed in the same direction such as, for example, in the direction from the first wiring structure 140 toward the core substrate 110 and the passive component 120, but is not limited thereto.

The first wiring structure 140 may be disposed on one surface 120s1 of the passive component 120, and thus the one surface 120s1 on which the electrode 122 of the passive component 120 is disposed may face the first wiring structure 140. A semiconductor package may be disposed on the first wiring structure 140, and the electrode 122 of the passive component 120 may be connected to the semiconductor package through a short electrical path through the first wiring structure 140.

The first wiring structure 140 may include a first wiring layer 142A disposed on the encapsulant 130, a first insulating layer 141 disposed on the encapsulant 130 and covering the first wiring layer 142A, a second wiring layer 142B disposed on the first insulating layer 141, and a fourth via 143 penetrating the first insulating layer 141 and electrically connecting the second wiring layer 142B to the first wiring layer 142A. However, embodiments are not limited thereto, and the first wiring structure 140 may include more or fewer insulating layers and/or wiring layers than shown in the drawing. For example, the first wiring structure 140 may include only the first wiring layer 142A and may not include the first insulating layer 141 and the second wiring layer 142B, or may further include additional insulating and wiring layers disposed on the first insulating layer 141.

As a material of the first insulating layer 141, an insulating material may be used, and for example, at least one from among a thermosetting resin such as an epoxy resin, a thermoplastic resin such as polyimide, a prepreg (PPG), an Ajinomoto build-up film (ABF), and FR-4 may be used.

A conductive material may be used as the material of each of the first wiring layer 142A and the second wiring layer 142B, and each of them may include, for example, copper (Cu), aluminum (Al), nickel (Ni), gold (Au), platinum (Pt), silver (Ag), or an alloy thereof.

As the material of the fourth via 143, the same material as a material of the first wiring layer 142A and/or the second wiring layer 142B may be used. The fourth via 143 may be integrally formed with the second wiring layer 142B disposed thereon, and may not have a boundary with the second wiring layer 142B. The fourth via 143 may have a tapered shape whose width narrows in the direction from the second wiring layer 142B to the first wiring layer 142A, but is not limited thereto.

The second wiring structure 150 is disposed on the other surface of the core substrate 110 and may be electrically connected to the core substrate 110. The encapsulant 130 may be present between the second wiring structure 150 and one surface of the core substrate 110. For electrical connection between the second wiring structure 150 and the core substrate 110, the passive component embedded substrate 100A may further include a third via V3 that penetrates the encapsulant 130 to electrically connect the second wiring structure 150 to the second core wiring layer 112B of the core substrate 110.

A conductive material may be used as the material of the third via V3, and the third via V3 may include, for example, copper (Cu), aluminum (Al), nickel (Ni), gold (Au), platinum (Pt), silver (Ag), or an alloy thereof. In the process, the third via V3 may have a shape tapered in a direction opposite to the taper direction of the first via V1 and the second via V2, but is not limited thereto.

The second wiring structure 150 may be disposed on the other surface 120s2 of the passive component 120, and thus the thickness supplementary layer TC attached to the other surface 120s2 of the passive component 120 may face the second wiring structure 150.

The second wiring structure 150 may include a third wiring layer 152A disposed on the encapsulant 130, a second insulating layer 151 disposed on the encapsulant 130 and covering the third wiring layer 152A, a fourth wiring layer 152B disposed on the second insulating layer 151, and a fifth via 153 penetrates the second insulating layer 151 and electrically connects the fourth wiring layer 152B to the third wiring layer 152A. However, embodiments are not limited thereto, and the second wiring structure 150 may include more or fewer insulating layers and/or wiring layers than shown in the drawing. For example, the second wiring structure 150 may include only the third wiring layer 152A and may not include the second insulating layer 151 and the third wiring layer 152A, or may further include additional insulating and wiring layers disposed on the second insulating layer 151. In addition, the numbers of the insulating layers and/or the wiring layers included in the first wiring structure 140 and the second wiring structure 150 may be the same, or may be different from each other.

As a material of the second insulating layer 151, an insulating material may be used, and for example, at least one from among a thermosetting resin such as an epoxy resin, a thermoplastic resin such as polyimide, a prepreg (PPG), an Ajinomoto build-up film (ABF), and FR-4 may be used.

A conductive material may be used as the material of each of the third wiring layer 152A and the fourth wiring layer 152B, and each of them may include, for example, copper (Cu), aluminum (Al), nickel (Ni), gold (Au), platinum (Pt), silver (Ag), or an alloy thereof.

As the material of the fifth via 153, the same material as a material of the third wiring layer 152A and/or the fourth wiring layer 152B may be used. The fifth via 153 may be integrally formed with the fourth wiring layer 152B disposed thereon, and may not have a boundary with the fourth wiring layer 152B. The fifth via 153 may have a tapered shape whose width narrows in the direction from the fourth wiring layer 152B to the third wiring layer 152A, but is not limited thereto.

The first protective layer 160 and the second protective layer 170 may protect the first wiring structure 140 and the second wiring structure 150, respectively. The first protective layer 160 may be disposed on the first wiring structure 140, and the second protective layer 170 may be disposed on the second wiring structure 150. Each of the first protective layer 160 and the second protective layer 170 may have openings that expose each of the pads of the second wiring layer 142B and the fourth wiring layer 152B.

As a material of each of the first protective layer 160 and the second protective layer 170, an insulating material such as, for example, a solder resist may be used.

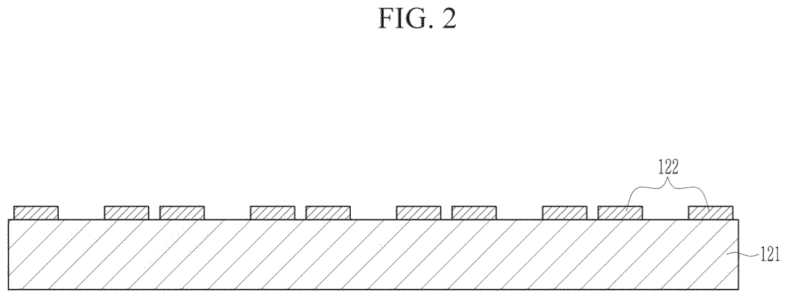

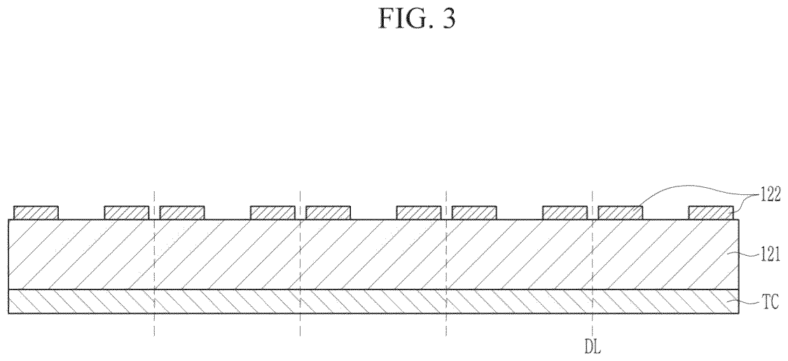

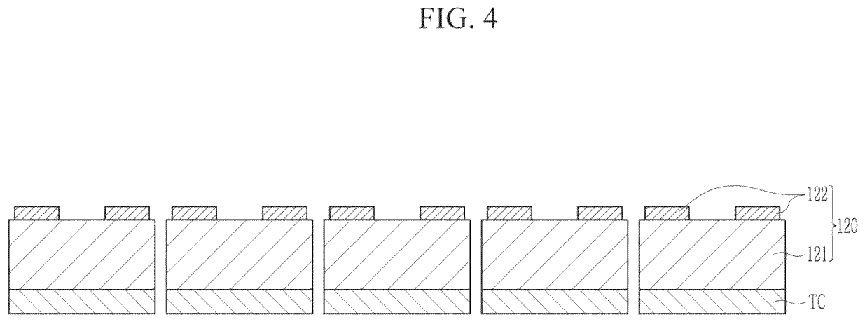

FIG. 2 to FIG. 15 illustrate manufacturing process diagrams of a passive component embedded substrate according to an embodiment of the present disclosure.

Referring to FIG. 2 to FIG. 4, first, by forming a wafer-like passive component including the semiconductor substrate 121 and the electrode 122, attaching the thickness supplementary layer TC onto the semiconductor substrate 121, and then dicing the wafer-like passive component along the dicing line DL, a plurality of the passive component 120 to which the thickness supplementary layer TC is attached may be manufactured.

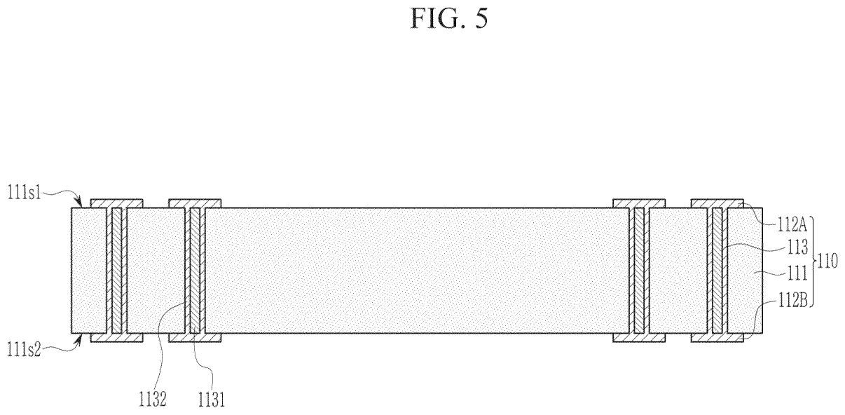

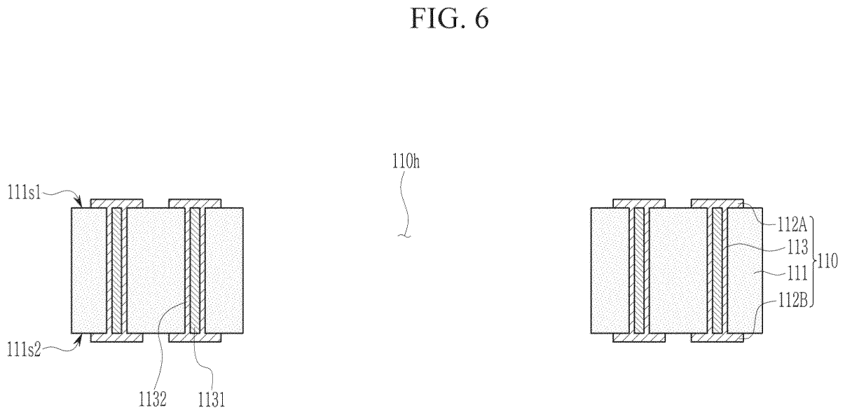

Next, referring to FIG. 5 and FIG. 6, the cavity 110h is formed through the core substrate 110 including the core insulating layer 111, the core wiring layers (e.g., the first core wiring layer 112A and the second core wiring layer 112B), and the through via 113. The method of forming the cavity 110h is not particularly limited, and methods such as a mechanical drilling method and a laser drilling method may be used.

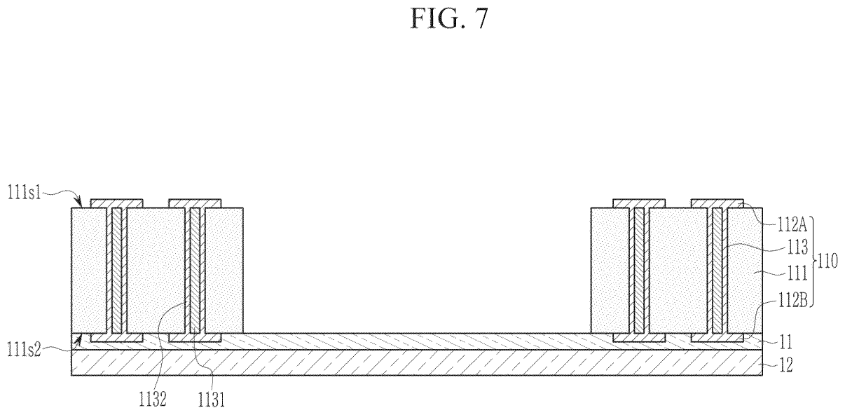

Next, referring to FIG. 7, the core substrate 110 is attached to an adhesive film 11 disposed on a carrier substrate 12. The adhesive film 11 may be relatively flexibility, the second wiring layer 142B may be embedded into the adhesive film 11, and one surface 111s2 of the core insulating layer 111 may be attached to the adhesive film 11.

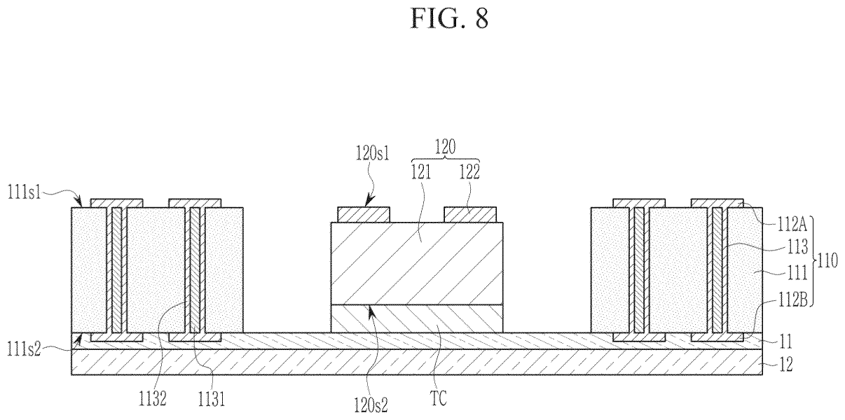

Next, referring to FIG. 8, the passive component 120 to which the thickness supplement layer TC is attached is disposed in the cavity 110h. In this case, the passive component 120 may be disposed in the cavity 110h such that the thickness supplementary layer TC is attached to the adhesive film 11.

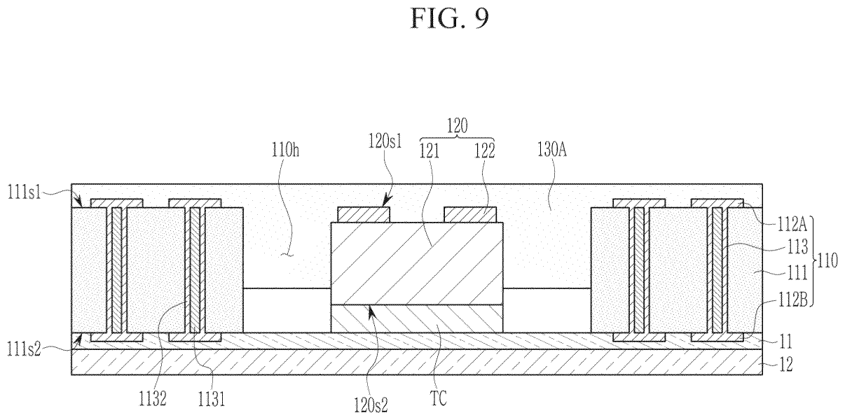

Next, referring to FIG. 9, first lamination is performed with a first encapsulant 130A. The first encapsulant 130A may fill a portion of the cavity 110h and cover one surface of the core substrate 110 and one surface 120s1 of the passive component 120.

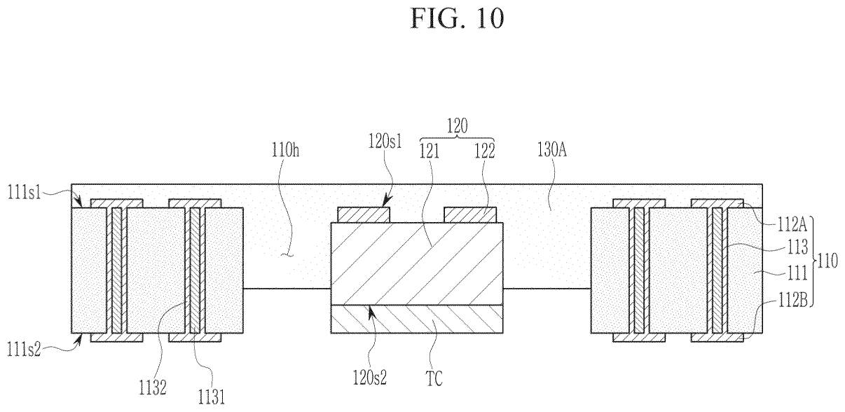

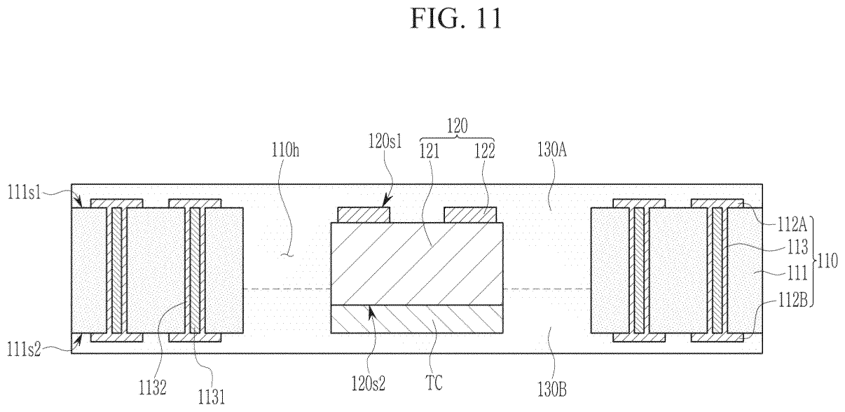

Next, referring to FIG. 10 and FIG. 11, the carrier substrate 12 and the adhesive film 11 are removed, and secondary lamination is performed using a second encapsulant 130B. The second encapsulant 130B may fill the remaining portion of the cavity 110h and cover the other side of the core substrate 110 and the thickness supplementary layer TC.

The first encapsulant 130A and the second encapsulant 130B may be integrated with each other to form the encapsulant 130 of the passive component embedded substrate 100A, and may not have a boundary that may be visually identified with each other depending on process conditions such as lamination materials, temperature, or pressure. However, a boundary may exist between the first encapsulant 130A and the second encapsulant 130B.

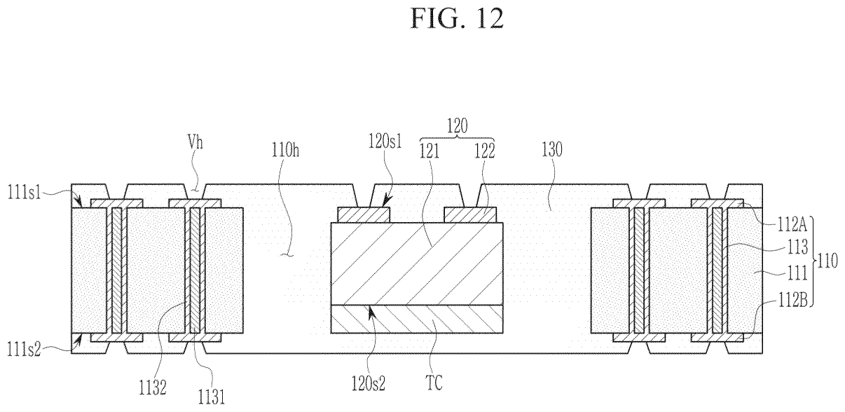

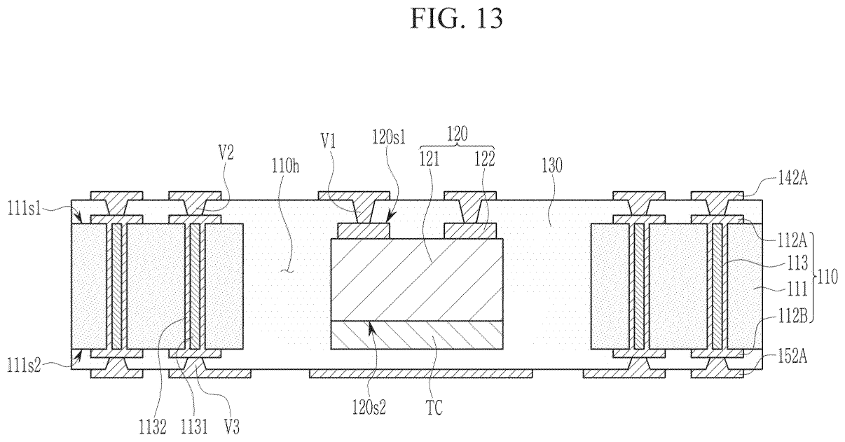

Next, referring to FIG. 12 and FIG. 13, via holes Vh are formed in the encapsulant 130, and the first via V1, the second via V2, and the third via V3 may be formed by filling the via holes Vh. In this case, the first wiring layer 142A may be formed together with the first via V1 and the second via V2, and the third wiring layer 152A may be formed together with the third via V3.

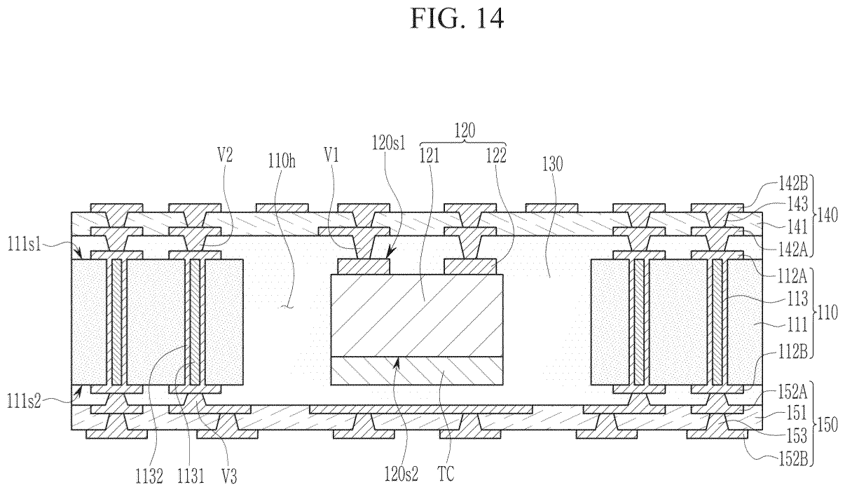

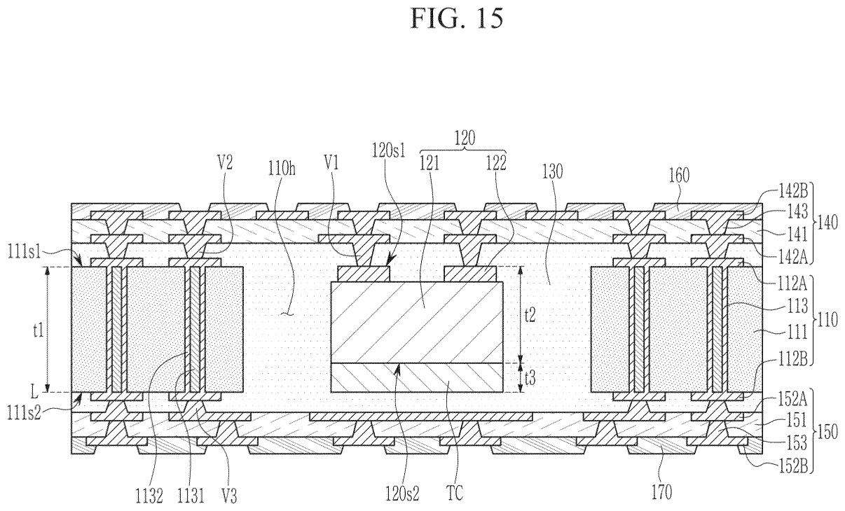

Next, referring to FIG. 14 and FIG. 15, an insulating layer, a via, and a wiring layer are sequentially formed on two surfaces of the encapsulant 130 to form the first wiring structure 140 and the second wiring structure 150, respectively, and then the first protective layer 160 and the second protective layer 170 may be formed on the first wiring structure 140 and the second wiring structure 150, respectively, to manufacture the passive component-embedded substrate 100A according to the embodiment.

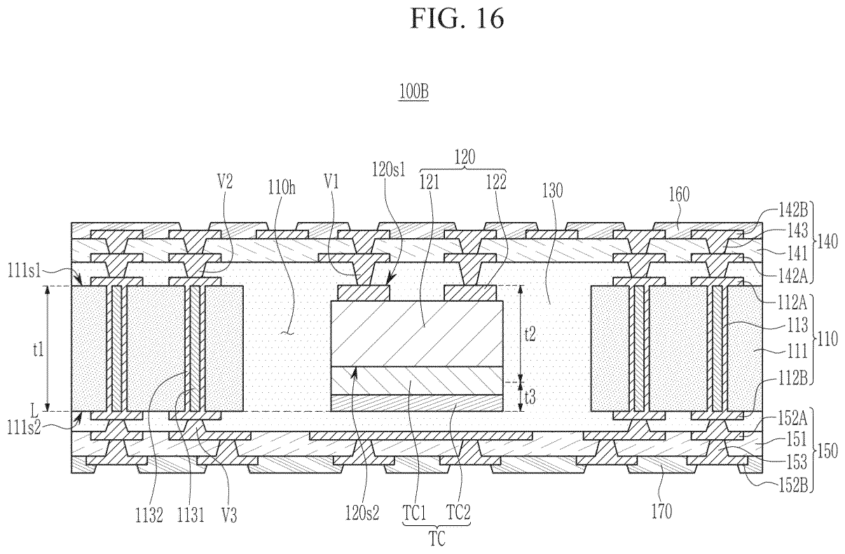

FIG. 16 illustrates a cross-sectional view of a passive component embedded substrate according to another embodiment of the present disclosure.

A thickness supplementary layer TC of a passive component embedded substrate 100B may include a plurality of layers. For example, the thickness supplementary layer TC may include a first layer TC1 and a second layer TC2 disposed on the first layer TC1. The first layer TC1 and the second layer TC2 may be sequentially disposed on the passive component 120, and thus the first layer TC1 may be disposed between the passive component 120 and the second layer TC2. The first layer TC1 may be an adhesive film, and the second layer TC2 may be a conductive tape or a conductive foil, but are not limited thereto. When the thickness of the passive component 120 is very thin, the second layer TC2 may additionally supplement the thickness t2 of the passive component 120 together with the first layer TC1.

In addition, the details specifically described in the description of the passive component embedded substrate 100A according to the embodiment of the present disclosure may be equally applied to the description of other components.

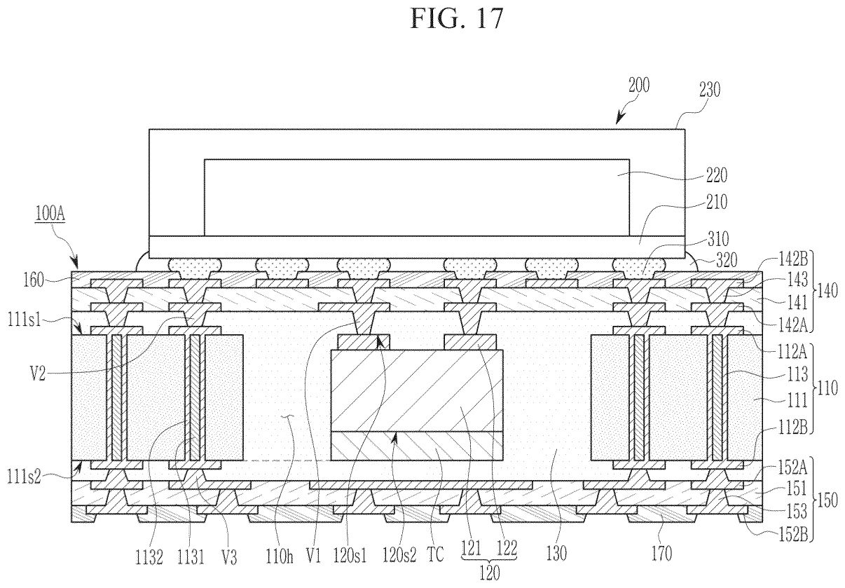

FIG. 17 illustrates a cross-sectional view of a semiconductor package including a passive component embedded substrate according to an embodiment of the present disclosure.

A semiconductor chip 220 may be mounted on the passive component embedded substrate 100A. The semiconductor chip 220 may be mounted on the passive component embedded substrate 100A in the form of a separately packaged sub-semiconductor package 200 (also referred to as a semiconductor package) as shown in FIG. 17. However, according to embodiments, the semiconductor chip 220 may be mounted in the form of an unpacked bare chip.

The semiconductor chip 220 or the sub-semiconductor package 200 is disposed on the passive component embedded substrate 100A, and may be electrically connected to the passive component embedded substrate 100A. The semiconductor chip 220 or the sub-semiconductor package 200 may be connected to the passive component 120 through a short electrical path through the first wiring structure 140.

The semiconductor chip 220 or the sub-semiconductor package 200 may be mounted on the passive component embedded substrate 100A through a conductive bump 310, and the conductive bump 310 may be covered with an underfill resin 320.

The sub-semiconductor package 200 may include a substrate 210, a semiconductor chip 220 disposed on the substrate 210, and an encapsulant 230 covering the semiconductor chip 220. The type of the sub-semiconductor package 200 is not particularly limited, and the sub-semiconductor package 200 may be, for example, a flip chip package, a fan-in wafer level package (FOWLP), or a fan-out wafer level package (FOWLP).

The substrate 210 may be a known substrate commonly used in a semiconductor package field, and may include an insulating layer and a wiring layer. The semiconductor chip 220 may be redistributed through the substrate 210 and/or may be electrically connected to the passive component embedded substrate 100A.

The type of the semiconductor chip 220 is also not particularly limited, and the semiconductor chip 220 may be various types of chips such as a logic chip, a memory chip, and a system-on-chip (SOC).

The encapsulant 230 may protect the semiconductor chip 220 from physical, mechanical, and chemical damage. As the material of the encapsulant 230, an insulating material such as an epoxy mold compound (EMC) may be used.

Meanwhile, the sub-semiconductor package 200 may be mounted not only on the passive component embedded substrate 100A according to the embodiment, but also on the passive component embedded substrate 100B according to another embodiment.

While non-limiting example embodiments of the present disclosure have been described with reference to the drawings, it is to be understood that the present disclosure is not limited to the example embodiments. On the contrary, various modifications and equivalent arrangements are included within the spirit and scope of the present disclosure.

What is claimed is:

1. A passive component embedded substrate comprising:
a core substrate including a core insulating layer that includes a cavity;
a passive component;
a thickness supplementary layer attached to a first surface of the passive component; and
an encapsulant that fills the cavity and is on the passive component,
wherein the thickness supplementary layer and at least a portion of the passive component is within the cavity.

2. The passive component embedded substrate of claim 1, wherein
a sum of a thickness of the passive component and a thickness of the thickness supplementary layer is equal to or greater than a thickness of the core insulating layer.

3. The passive component embedded substrate of claim 1, wherein
a first surface of the thickness supplementary layer, that is opposite to a second surface of the thickness supplementary layer that is attached to the passive component, is coplanar with a surface of the core insulating layer.

4. The passive component embedded substrate of claim 1, wherein
a side surface of the thickness supplementary layer is coplanar with a side surface of the passive component.

5. The passive component embedded substrate of claim 1, wherein
the thickness supplementary layer comprises an adhesive film.

6. The passive component embedded substrate of claim 5, wherein
the thickness supplementary layer further comprises a conductive tape or a conductive foil, and
the adhesive film is between the passive component and the conductive tape or between the passive component and the conductive foil.

7. The passive component embedded substrate of claim 1, wherein
the encapsulant is on a first surface of the thickness supplementary layer that is opposite to a second surface of the thickness supplementary layer that is attached to the passive component.

8. The passive component embedded substrate of claim 1, wherein
the encapsulant is on at least one from among two surfaces of the core substrate that face away from each other.

9. The passive component embedded substrate of claim 1, wherein
the passive component is a silicon capacitor.

10. The passive component embedded substrate of claim 1, wherein
a thickness of the passive component is thinner than a thickness of the core insulating layer.

11. The passive component embedded substrate of claim 1, further comprising a wiring structure on a surface of the core substrate.

12. A passive component embedded substrate comprising:
a core substrate comprising:
a core insulating layer that includes a cavity;
a first core wiring layer and a second core wiring layer respectively on two surfaces of the core insulating layer that face away from each other; and
a through via that penetrates the core insulating layer such as to electrically connect the first core wiring layer and the second core wiring layer;
a passive component comprising an electrode on a first surface of the passive component;
a thickness supplementary layer attached to a second surface of the passive component, that is opposite to the first surface;
an encapsulant on the passive component;
a first wiring structure on the first surface of the passive component and electrically connected to each of the core substrate and the passive component; and
a second wiring structure on the second surface of the passive component and electrically connected to the core substrate,
wherein the thickness supplementary layer and at least a portion of the passive component is within the cavity.

13. The passive component embedded substrate of claim 12, wherein
the through via comprises an insulating material and a conductive material surrounding the insulating material.

14. The passive component embedded substrate of claim 12, wherein
the encapsulant is on the two surfaces of the core substrate that face away from each other, and
the passive component embedded substrate further comprises:
a first via penetrating the encapsulant such as to electrically connect the first wiring structure to the electrode of the passive component;
a second via penetrating the encapsulant such as to electrically connect the first wiring structure to the first core wiring layer; and
a third via penetrating the encapsulant such as to electrically connect the second wiring structure to the second core wiring layer.

15. The passive component embedded substrate of claim 14, wherein
the third via is tapered in a direction opposite to a direction in which the first via and the second via are tapered.

16. The passive component embedded substrate of claim 12, further comprising:
a first protective layer on the first wiring structure; and
a second protective layer on the second wiring structure.

17. A semiconductor package comprising:
a passive component embedded substrate; and
a semiconductor chip on the passive component embedded substrate and electrically connected to the passive component embedded substrate,
wherein the passive component embedded substrate comprises:
a core substrate comprising a core insulating layer including a cavity;
a passive component comprising an electrode on a first surface of the passive component;
a thickness supplementary layer attached to a second surface of the passive component, that is opposite to the first surface;
an encapsulant on the passive component;
a first wiring structure on the first surface of the passive component and electrically connected to each of the core substrate and the passive component; and
a second wiring structure on the second surface of the passive component and electrically connected to the core substrate,
wherein a thickness of the passive component is 600 μm to 780 μm,
wherein a thickness of the core insulating layer is thicker than the thickness of the passive component, and
wherein the semiconductor chip is electrically connected to the passive component by the first wiring structure.

18. The semiconductor package of claim 17, wherein
the thickness of the core insulating layer is 800 μm or more.

19. The semiconductor package of claim 17, wherein
the thickness of the passive component is 50% to 75% of the thickness of the core insulating layer.

20. The semiconductor package of claim 17, wherein
the passive component is a silicon capacitor comprising the electrode and a semiconductor substrate, and
the thickness supplementary layer is attached to the semiconductor substrate.
